(19) United States
(12) Patent Application Publication
(10) Pub. No.: US 2014/0151760 A1
(43) Pub. Date: Jun. 5, 2014

(54) DOPED FLOWABLE PRE-METAL DIELECTRIC

(71) Applicants: Haiting WANG, Clifton Park, NY (US); Po-Wen CHAN, Clifton Park, NY (US); Yan Ping SHEN, Saratoga Springs, NY (US); Yong Meng LEE, Mechanicville, NY (US)

(72) Inventors: Haiting WANG, Clifton Park, NY (US); Po-Wen CHAN, Clifton Park, NY (US); Yan Ping SHEN, Saratoga Springs, NY (US); Yong Meng LEE, Mechanicville, NY (US)

(73) Assignee: GLOBALFOUNDRIES Inc., Grand Cayman (KY)

(21) Appl. No.: 13/693,614

(22) Filed: Dec. 4, 2012

(51) Int. Cl. H01L 29/51; H01L 29/78

(52) U.S. Cl. CPC H01L 29/51; H01L 29/78
USPC 257/288; 438/585

(57) ABSTRACT

A method of filling gaps between gates with doped flowable pre-metal dielectric (PMD) and the resulting device are disclosed. Embodiments include forming at least two dummy gates on a substrate, each dummy gate being surrounded by spacers; filling a gap between adjacent spacers of the at least two dummy gates with a flowable PMD; implanting a dopant in the flowable PMD; and annealing the flowable PMD. Doping the flowable PMD prevents erosion of the PMD, thereby providing a voidless gap-fill.

### TECHNICAL FIELD

The present disclosure relates to filling gaps between gate electrodes in gate last process flows. The present disclosure is particularly applicable to filling gaps between gates for 20 nanometer (nm) technology node devices and beyond.

### BACKGROUND

With the continuous down scaling of transistors, PMD filling of gaps between gates has become more difficult. Flowable PMD is recognized as one solution for void-free gaps. Traditionally, a post anneal step is required to densify the flowable PMD. However, limited by the traditional thermal budget of middle-of-the-line (MOL) processing (e.g., <500° C.), the flowable PMD is still fragile post anneal. The weakness of the flowable PMD causes PMD loss during subsequent processing, such as oxide wet etching. The PMD loss is even more prominent in gate-last processing since dummy gate and gate oxide removal, inter-layer pre-clean, etc. cause recesses on the flowable PMD, leading to gate height loss, metal puddle issues, etc.

A need therefore exists for methodology for filling gaps between gates without forming voids and without gap-fill removal, and the resulting device.

### SUMMARY

An aspect of the present disclosure is an efficient method for forming doped flowable PMD gap-fill.

Another aspect of the present disclosure is a substrate with doped flowable PMD filling gaps between adjacent gates.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming at least two dummy gates on a substrate, each dummy gate being surrounded by spacers; filling a gap between adjacent spacers of the at least two dummy gates with a flowable PMD; implanting a dopant in the flowable PMD; and annealing the flowable PMD.

An aspect of the present disclosure includes the dopant being at least one of carbon and nitrogen. In another aspect, the dopant is implanted in the flowable PMD at a dose of greater than 5×10¹⁵/centimeter² (cm²). Another aspect includes annealing the flowable PMD at 500° C. for 2 hours. An aspect of the disclosure further includes removing the at least two dummy gates, forming cavities, and forming metal gates in the cavities subsequent to implanting the dopant and annealing the flowable PMD. An aspect also includes implanting the dopant in the flowable PMD prior to annealing the flowable PMD. A further aspect includes annealing the flowable PMD prior to implanting the dopant in the flowable PMD. Yet another aspect includes the flowable PMD including a flowable chemical vapor deposition (CVD) oxide or spin on glass (SOG). A further aspect includes the flowable CVD oxide including SiNxHy, oxygen and steam.

Another aspect of the present disclosure is a device including: at least two replacement metal gates surrounded by spacers above a substrate; and a doped and annealed flowable PMD filling a gap between adjacent spacers of the at least two replacement metal gates.

Aspects include the flowable PMD being doped with at least one of carbon and nitrogen. Another aspect includes the flowable PMD being doped at a dose of greater than 5×10¹⁵/cm². A further aspect includes the flowable PMD being annealed at 500° C. for 2 hours. An aspect includes the flowable PMD including a flowable CVD oxide or SOG. Yet another aspect includes the flowable CVD oxide including SiNxHy, oxygen, and steam. In another aspect, the flowable PMD filling the gap is free of a void. Another aspect includes a top surface of the flowable PMD being substantially co-planar with the spacers.

Another aspect of the present disclosure includes: forming dummy gates on a silicon substrate, each dummy gate surrounded by spacers; filling a gap between adjacent spacers of each pair of dummy gates with a flowable PMD comprising CVD oxide or SOG; doping the flowable PMD with at least one of carbon and nitrogen; annealing the flowable PMD; removing the dummy gates, forming cavities; and forming a high-k metal gate in each cavity, wherein the filled gaps are substantially free of voids. An additional aspect includes doping the flowable PMD at a dose of greater than 5×10¹⁵/cm². Yet another aspect includes annealing the flowable PMD at 500° C. for 2 hours.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 6 schematically illustrate a method for filling gaps between adjacent gates with a doped flowable PMD, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of voids or recesses attendant upon filling gaps between adjacent gates. In accordance with embodiments of the present disclosure, a doped flowable PMD is used to fill gaps between adjacent gates.

Methodology in accordance with embodiments of the present disclosure includes forming at least two dummy gates on a substrate, each dummy gate being surrounded by spacers. Between spacers of adjacent dummy gates is a gap that is filled with a flowable PMD. The flowable PMD may then be implanted with a dopant and annealed. The resulting doped flowable PMD fills the gap without voids and without being subsequently removed by additional processing steps.

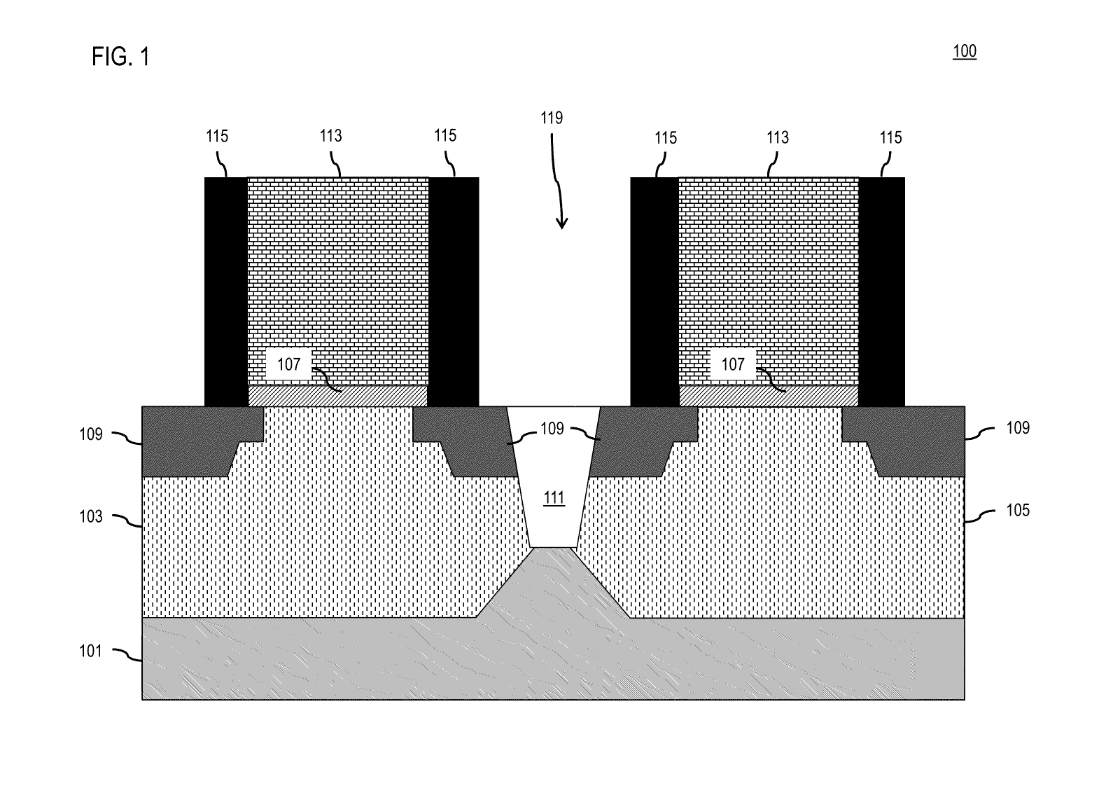

Adverting to FIG. 1, a method of filling a gap between spacers of adjacent dummy gates, according to an exemplary embodiment, begins with the structure 100 illustrated in FIG. 1. The structure 100 begins with the substrate 101, which may be a silicon substrate. The substrate 101 may be doped to form well regions 103 and 105. Between the well regions 103 and 105 may be a shallow trench isolation (STI) region 111. Above each of the well regions 103 and 105, a gate oxide 107 and dummy gate 113 may be formed, and a pair of spacers 115 may be formed surrounding each dummy gate 113. The spacers 115 are used as a mask for implanting dopants in the substrate 101 to form source/drain regions 109 at opposite sides of the dummy gates 113. Accordingly, between adjacent spacers 115 of the two dummy gates 113 may be a gap 119, as illustrated in FIG. 1.

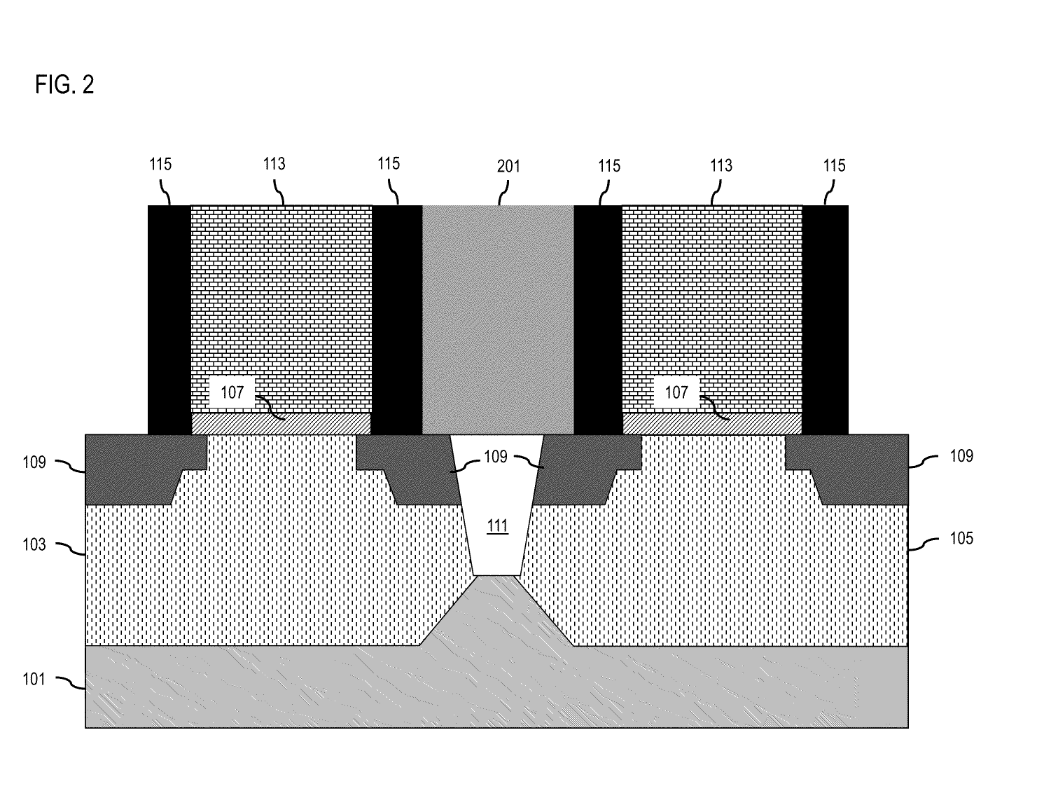

As illustrated in FIG. 2, the gap 119 is filled with a flowable PMD 201. The flowable PMD 201 may be a flowable CVD oxide, such as SiNxHy combined with oxygen and steam, or SOG. The flowable PMD 201 may fill the gap to be substantially co-planar with the spacers 115 and be free of voids.

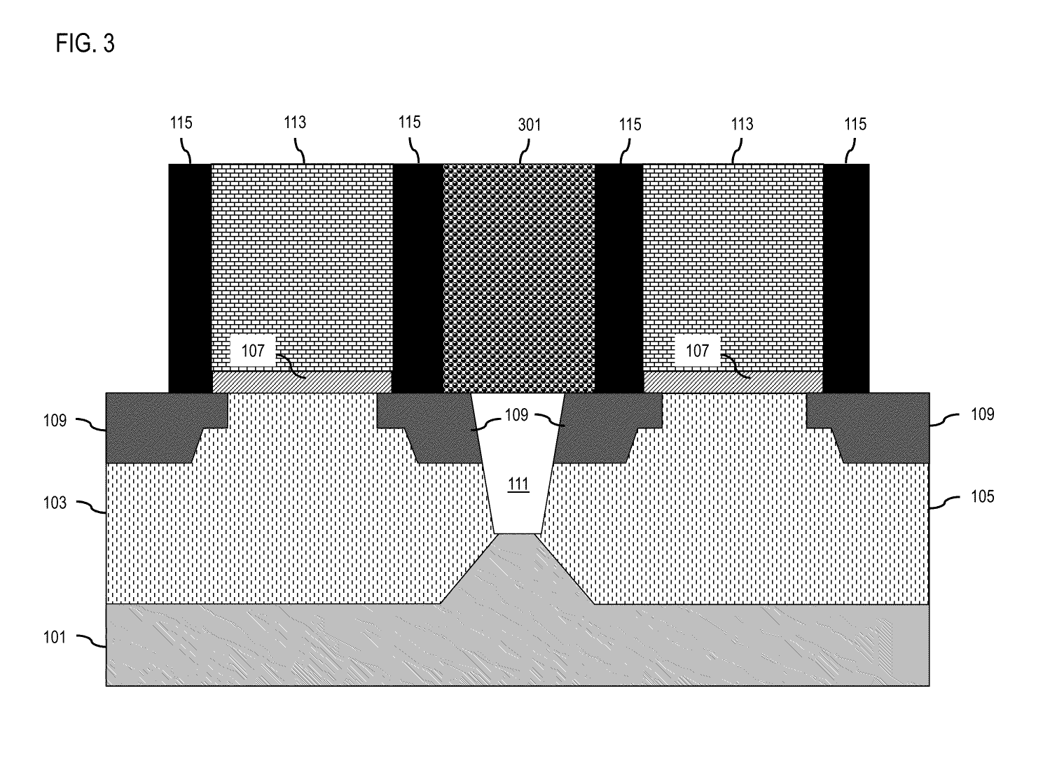

After filling the gap 119 with the flowable PMD 201, a dopant may be implanted into the flowable PMD 201 forming a doped flowable PMD 301, as illustrated in FIG. 3. The dopant may be at least one of carbon and nitrogen and may be implanted in the flowable PMD at a dose of greater than 5×10¹⁵/cm². Alternatively, the flowable PMD 301 may be in-situ doped with the dopant during the filling of the gap 119. By implanting a dopant within the flowable PMD 201, the dopant retards the wet etch rate of the PMD while the flowable property of the flowable PMD allows the PMD to fill the gap 119 without voids. This is particularly applicable to gate-last processes where previous flowable PMD suffered during etching from subsequent processing steps, such as wet etching the gate oxide. The doped flowable PMD 301, on the other hand, is robust with respect to dilute hydrofluoric acid processing steps, and the doping lowers the k-value of the PMD, which in turn reduces gate-to-contact capacitance of the final device.

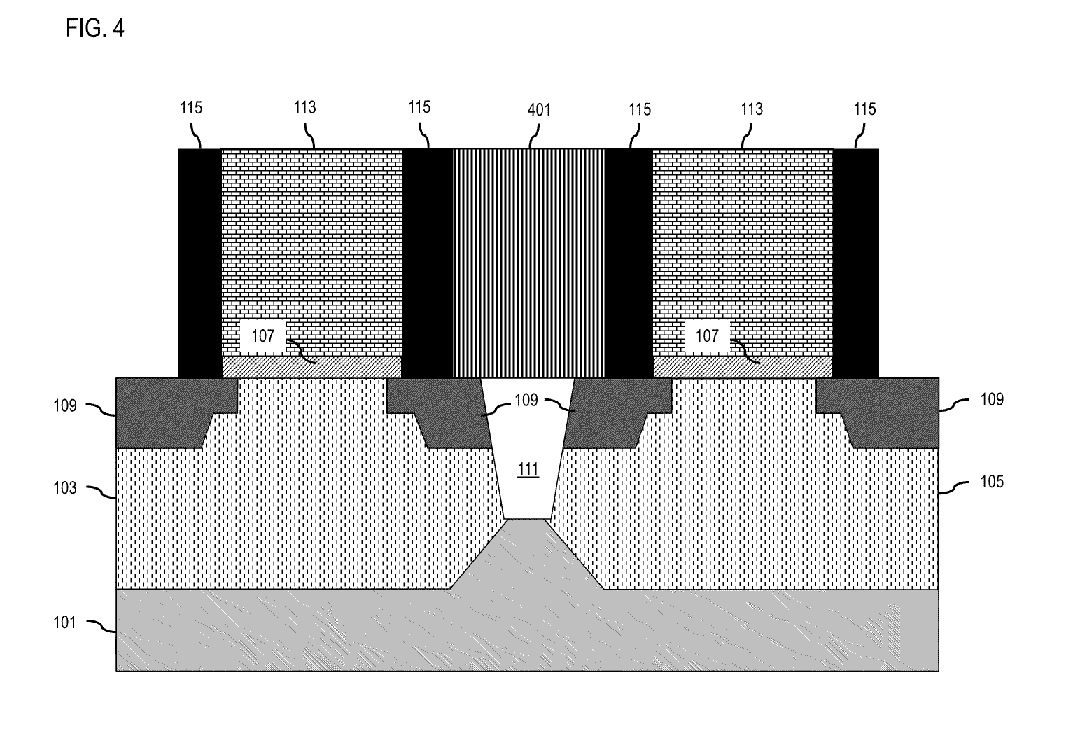

Adverting to FIG. 4, the doped flowable PMD 301 may be subsequently annealed to form a doped flowable PMD 401. The annealing may be at 500° C. for 2 hours. Thus, as illustrated and described, the flowable PMD 201 may first be implanted with a dopant and subsequently annealed. However, alternatively, the flowable PMD 201 may be annealed first and subsequently implanted with a dopant.

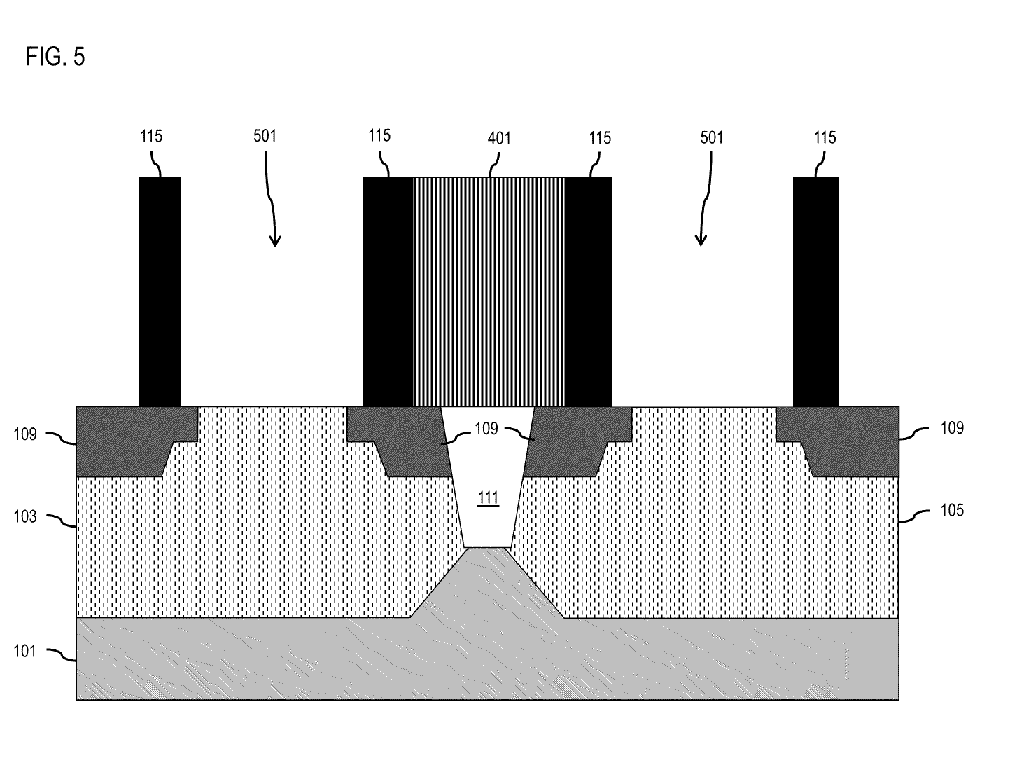

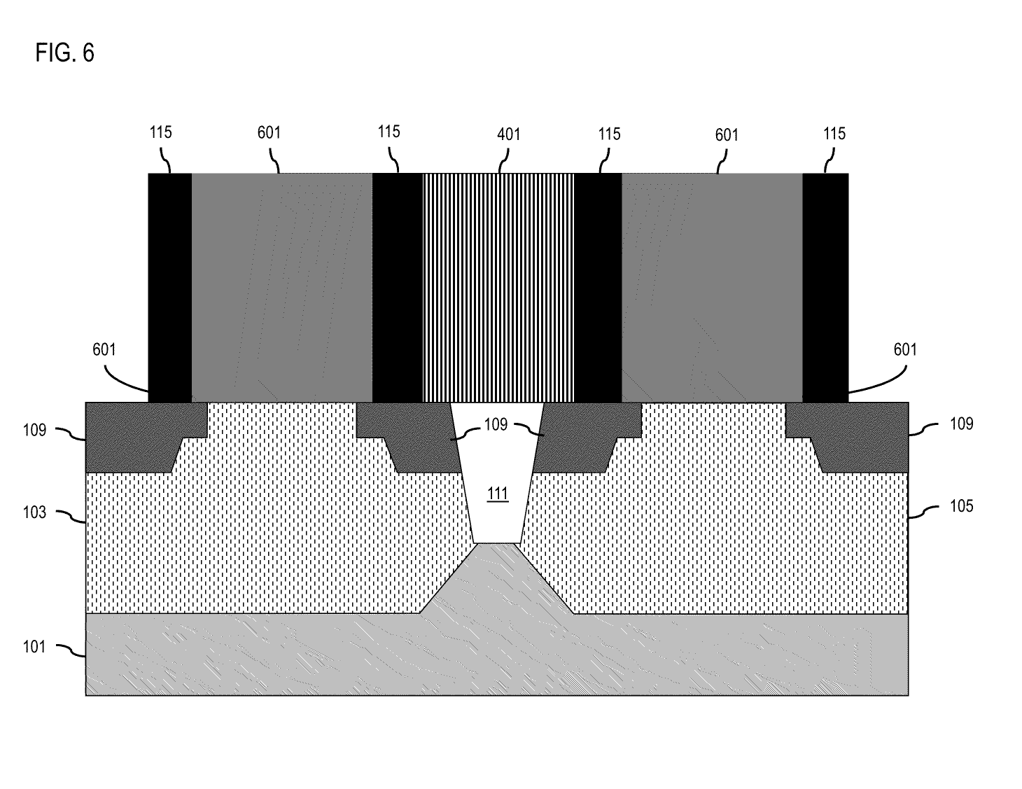

As illustrated in FIG. 5, subsequent processing of the dummy gates may occur, such as the dummy gates 113 being removed, forming cavities 501, followed by high-k metal gates 601 being formed in the cavities 501 (FIG. 6). Additional middle-of-the-line processing and back-end-of-the-line processing may occur without significant removal of the doped flowable PMD 401.

The embodiments of the present disclosure achieve several technical effects, including flowable PMD between gates that does not suffer from voids or wet etch removal, better gate height control, and a lower k-value of the PMD, resulting in reduced gate-to-contact capacitance. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming at least two dummy gates on a substrate, each dummy gate being surrounded by spacers;
filling a gap between adjacent spacers of the at least two dummy gates with a flowable pre-metal dielectric;
implanting a dopant in the flowable pre-metal dielectric; and
annealing the flowable pre-metal dielectric.

2. The method according to claim 1, wherein the dopant is at least one of carbon and nitrogen.

3. The method according to claim 1, comprising implanting the dopant in the flowable pre-metal dielectric at a dose of greater than 5×10¹⁵/centimeter² (cm²).

4. The method according to claim 1, comprising annealing the flowable pre-metal dielectric at 500° C. for 2 hours.

5. The method according to claim 1, further comprising removing the at least two dummy gates, forming cavities, and forming metal gates in the cavities subsequent to implanting the dopant and annealing the flowable pre-metal dielectric.

6. The method according to claim 1, comprising implanting the dopant in the flowable pre-metal dielectric prior to annealing the flowable pre-metal dielectric.

7. The method according to claim 1, comprising annealing the flowable pre-metal dielectric prior to implanting the dopant in the flowable pre-metal dielectric.

8. The method according to claim 1, the flowable pre-metal dielectric comprising a flowable chemical vapor deposition (CVD) oxide or spin on glass (SOG).

9. The method according to claim 8, wherein the flowable CVD oxide comprises SiNxHy, oxygen and steam.

10. A device comprising:
at least two replacement metal gates surrounded by spacers above a substrate; and
a doped and annealed flowable pre-metal dielectric filling a gap between adjacent spacers of the at least two replacement metal gates.

11. The device according to claim 10, wherein the flowable pre-metal dielectric is doped with at least one of carbon and nitrogen.

12. The device according to claim 10, wherein the flowable pre-metal dielectric is doped at a dose of greater than 5×10¹⁵/cm².

13. The device according to claim 10, wherein the flowable pre-metal dielectric is annealed at 500° C. for 2 hours.

14. The device according to claim 10, the flowable pre-metal dielectric comprising a flowable chemical vapor deposition (CVD) oxide or spin on glass (SOG).

15. The device according to claim 14, wherein the flowable CVD oxide comprises SiNxHy, oxygen and steam.

16. The device according to claim 10, wherein the flowable pre-metal dielectric filling the gap is free of a void.

17. The device according to claim 10, wherein a top surface of the flowable pre-metal dielectric is substantially co-planar with the spacers.

18. A method comprising:
forming dummy gates on a silicon substrate, each dummy gate surrounded by spacers;
filling a gap between adjacent spacers of each pair of dummy gates with a flowable pre-metal dielectric comprising chemical vapor deposition (CVD) oxide or spin on glass (SOG);
doping the flowable pre-metal dielectric with at least one of carbon and nitrogen;
annealing the flowable pre-metal dielectric;
removing the dummy gates, forming cavities; and
forming a high-k metal gate in each cavity,
wherein the filled gaps are substantially free of voids.

19. The method according to claim 1, comprising doping the flowable pre-metal dielectric at a dose of greater than 5×10¹⁵/cm².

20. The method according to claim 1, comprising annealing the flowable pre-metal dielectric at 500° C. for 2 hours.
